(19) United States
(12) Patent Application Publication
(10) Pub. No.: US 2010/0055834 A1
(43) Pub. Date: Mar. 4, 2010

(54) SEMICONDUCTOR DEVICE MANUFACTURING METHOD

(75) Inventor: Shinji OHUCHI, Tokyo (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI SEMICONDUCTOR CO., LTD., Tokyo (JP)

(21) Appl. No.: 12/550,754

(22) Filed: Aug. 31, 2009

(30) Foreign Application Priority Data
Sep. 3, 2008 (JP) 2008-225828

(51) Int. Cl. H01L 21/98

(52) U.S. Cl. 438/107; 257/E21.705

(57) ABSTRACT

An improved method of manufacturing a semiconductor device. The resulting semiconductor device operates properly even when a plurality of semiconductor chips is mounted. One or more semiconductor chips are mounted on the bottom surface of a mounting substrate, the semiconductor chips are fixed to a supporting substrate with adhesive, and then the semiconductor chips are sealed with resin. Subsequently, another semiconductor chips are mounted on the top surface of the mounting substrate.

### BACKGROUND OF THE INVENTION

1. Field of the Invention

The present invention relates to a method of manufacturing a semiconductor device that includes a plurality of semiconductor chips.

2. Description of the Related Art

In recent years, in order to achieve many functions in a single semiconductor package, a plurality of semiconductor chips is mounted at high density on a single semiconductor package. FIG. 1 of the accompanying drawings shows an example of a high density semiconductor package 20. A plurality of semiconductor chips 22 is mounted on a silicon substrate 21. The silicon substrate 21 is connected to the semiconductor chips 22 by microbumps 23. The semiconductor chips 22 are sealed with resin 24. The silicon substrate 21 is mounted on a printed circuit board 25. The silicon substrate 21 is electrically connected to the circuit board 25 by with wires 26.

When manufacturing this type of semiconductor device 20, the semiconductor chips 22 mounted on the silicon substrate 21 are sealed with the resin 24, and then the silicon substrate 21 is mounted on the printed circuit board 25. For example, the method of manufacturing semiconductor devices disclosed in Japanese Patent Application Kokai (Laid-open) No. 2006-19433 uses this procedure (for example, the method of manufacturing shown in FIG. 3 and FIG. 4 of this Japanese publication).

### SUMMARY OF THE INVENTION

In the conventional manufacturing method as described above, warping of the silicon substrate 21 is caused by thermal shrinkage of the resin 24 that buries the semiconductor chips 22. As a result it is not possible to properly mount the silicon substrate 21 onto the printed circuit board 25, or the semiconductor device 20 does not operate properly due to a faulty connection between the silicon substrate 21 and the printed circuit board 25.

It is an object of the present invention to provide a semiconductor device manufacturing method, which can produce a semiconductor device that operates properly even when a plurality of semiconductor chips is mounted on a single substrate.

According to one aspect of the present invention, there is provided a method of manufacturing a semiconductor device that has a plurality of semiconductor chips. The semiconductor device manufacturing method includes a substrate preparation step of preparing a mounting substrate and a supporting substrate. The semiconductor device manufacturing method also includes a bottom surface mounting step of mounting at least one semiconductor chip on a bottom surface of the mounting substrate. The semiconductor device manufacturing method also includes a chip fixing step of fixing the semiconductor chip(s) mounted on the bottom surface of the mounting substrate, to one surface of the supporting substrate using adhesive or a mechanical gripper. The manufacturing method also includes a resin sealing step of sealing the semiconductor chip(s) mounted on the bottom surface of the mounting substrate using resin. The manufacturing method also includes a top surface mounting step of mounting at least one second semiconductor chip on a top surface of the mounting substrate.

According to the semiconductor device manufacturing method of the present invention, warping of the supporting substrate does not occur in the manufacturing process. Thus, the resulting semiconductor device operates properly even when a plurality of semiconductor chips is mounted.

The semiconductor device manufacturing method may also include an electrode forming step of providing at least one penetrating electrode that extends from the top surface to the bottom surface of the mounting substrate. The electrode forming step is carried out prior to the bottom surface mounting step.

First electrode pads may be provided on the first semiconductor chip(s), and the bottom surface mounting step may be carried out such that the first electrode pads are electrically connected to the penetrating electrode(s).

Second electrode pads may be provided on the second semiconductor chip(s), and the top surface mounting step may be carried out such that the second electrode pads are electrically connected to the penetrating electrode(s).

According to another aspect of the present invention, there is provided another method of manufacturing a semiconductor device that has a plurality of semiconductor chips. This manufacturing method includes a wafer preparation step of preparing a wafer that has a plurality of mounting substrates. The manufacturing method also includes a substrate preparation step of preparing a plurality of supporting substrates. The manufacturing method also includes a bottom surface mounting step of firmly mounting at least one semiconductor chip on a bottom surface of each of the mounting substrates on the wafer. The manufacturing method also includes a dicing step of dicing the wafer to obtain a plurality of individual mounting substrates. The manufacturing method also includes a chip fixing step of fixing the semiconductor chip(s) mounted on the bottom surface of each individual mounting substrate, to one surface of each supporting substrate. The manufacturing method also includes a resin sealing step of sealing the semiconductor chip(s) mounted on the bottom surface of each individual mounting substrate using resin. The manufacturing method also includes a top surface mounting step of mounting at least one second semiconductor chip on a top surface of each individual mounting substrate.

These and other objects, aspects and advantages of the present invention will become apparent to those skilled in the art from the following detailed description when read and understood in conjunction with the appended claims and drawings.

### BRIEF DESCRIPTION OF THE DRAWINGS

FIG. 1 illustrates a semiconductor device manufactured by a conventional manufacturing method;

FIG. 2 illustrates a semiconductor device manufactured by the manufacturing method according to a first embodiment of the present invention;

FIG. 3 is a flowchart showing the manufacturing process for the semiconductor device shown in FIG. 2;

FIG. 4A to FIG. 4E show a series of manufacturing steps for the semiconductor device shown in FIG. 2;

FIG. 5 illustrates a bottom view of a mounting substrate for semiconductor chips when the semiconductor chips are arranged on the mounting substrate side by side in the horizontal direction; and

FIG. 6 is a flowchart showing another manufacturing process for the semiconductor device according to a second embodiment of the present invention.

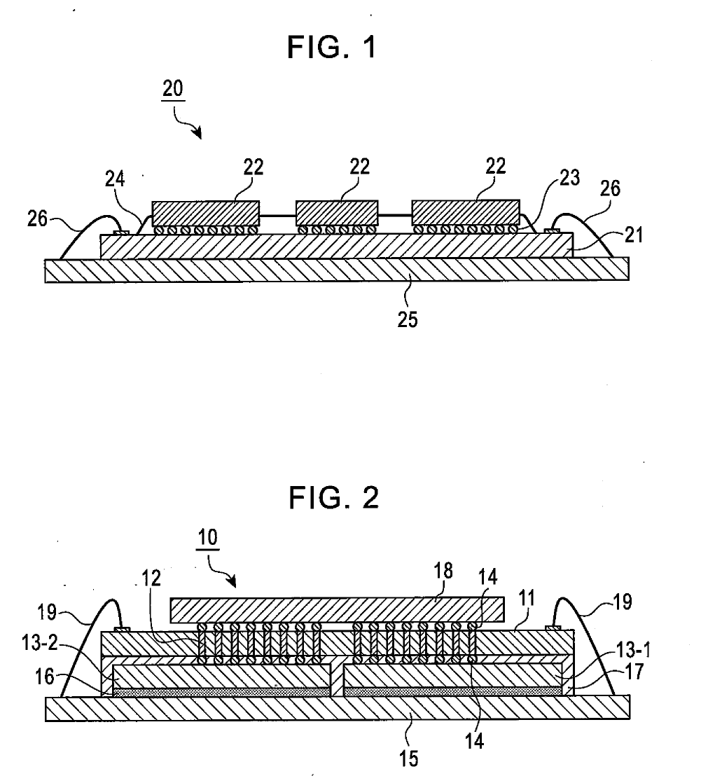

### DETAILED DESCRIPTION OF THE INVENTION

The following is a detailed explanation of the embodiments of the present invention with reference to the attached drawings. FIG. 2 shows a semiconductor device 10 manufactured by the manufacturing method according to the first embodiment.

A mounting substrate 11 is for example a silicon substrate. The mounting substrate 11 is one of a plurality of substrates obtained by separating a plurality of substrates formed on a single silicon wafer into individual substrates. “Separating into individual substrates” means dicing (i.e., cutting the silicon wafer to obtain the individual substrates). Penetrating electrodes 12 are provided penetrating the mounting substrate 11 from the top surface to the bottom surface. The penetrating electrodes 12 are made from an electrically conducting material. It should be noted that there is no limitation on the number or arrangement of the penetrating electrodes 12 in the mounting substrate 11, and a plurality of penetrating electrodes 12 may be arranged for example in a square or rectangular lattice shape or in an inclined lattice shape. The material of the penetrating electrodes 12 is for example copper or the like. A wiring layer, which is not shown on the drawings, is formed on the mounting substrate 11, and the wiring (not shown on the drawings) formed in the wiring layer is electrically connected to the penetrating electrodes 12.

Semiconductor chips 13-1 and 13-2 are fixed to the bottom surface of the mounting substrate 11 using lower bumps 14. Similarly, another semiconductor chip 18 is fixed to the top surface of the mounting substrate 11 using upper bumps 14. A plurality of electrodes (not shown on the drawings) is formed on each of the semiconductor chips 13-1, 13-2, and 18, and these electrodes are electrically connected to the bumps 14. The bumps 14 and the penetrating electrodes 12 are physically and electrically connected to each other. The bumps 14 are for example ball grid array (BGA) bumps or the like, and their material is copper, for example. The area around the penetrating electrodes 12 and the bumps 14 is given an appropriate electrically insulating process, to prevent short circuits.

The semiconductor chips 13-1, 13-2 are fixed to a supporting substrate 15 using adhesive 16. The material of the adhesive 16 can be any suitable material; it may be an epoxy adhesive, for example. The supporting substrate 15 is, for example, a common printed circuit board or the like. The semiconductor chips 13-1, 13-2 are sealed in their entirety with resin 17. The resin 17 is filled between the bottom surface of the mounting substrate 11 and the top surface of the supporting substrate 15 to stiffen and protect the semiconductor chips 13-1 and 13-2. The resin 17 is for example, an epoxy resin that includes a filler such as silica with diameter of several μm.

Electrodes (not shown on the drawings) formed on the surface of the mounting substrate 11 are electrically connected to electrodes (not shown on the drawings) formed on the surface of the supporting substrate 15 by wiring 19. The material of the wiring 19 is, for example, aluminum or the like. The functions achieved by the semiconductor device 10 may be any suitable functions. For example the semiconductor chip 13-1 may be a logic chip for calculation, the semiconductor chip 13-2 may be a memory chip for storage, and the semiconductor device 10 may be a simulation device using the calculation and storage functions.

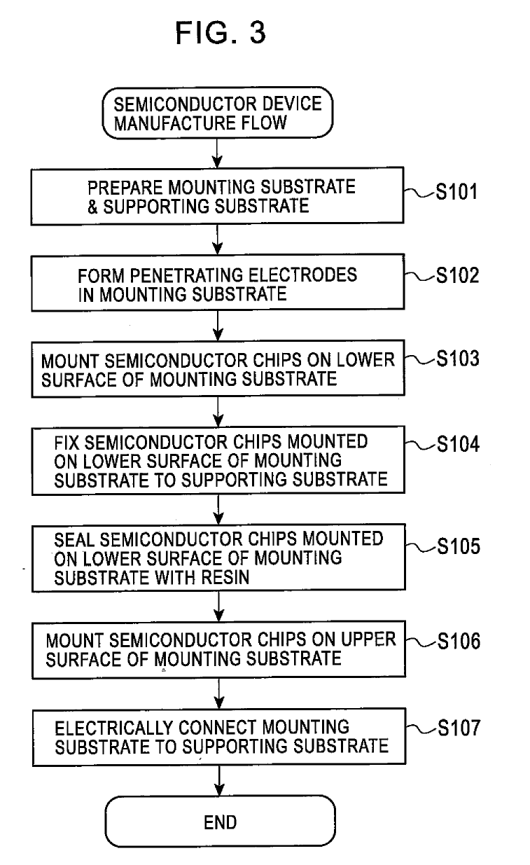

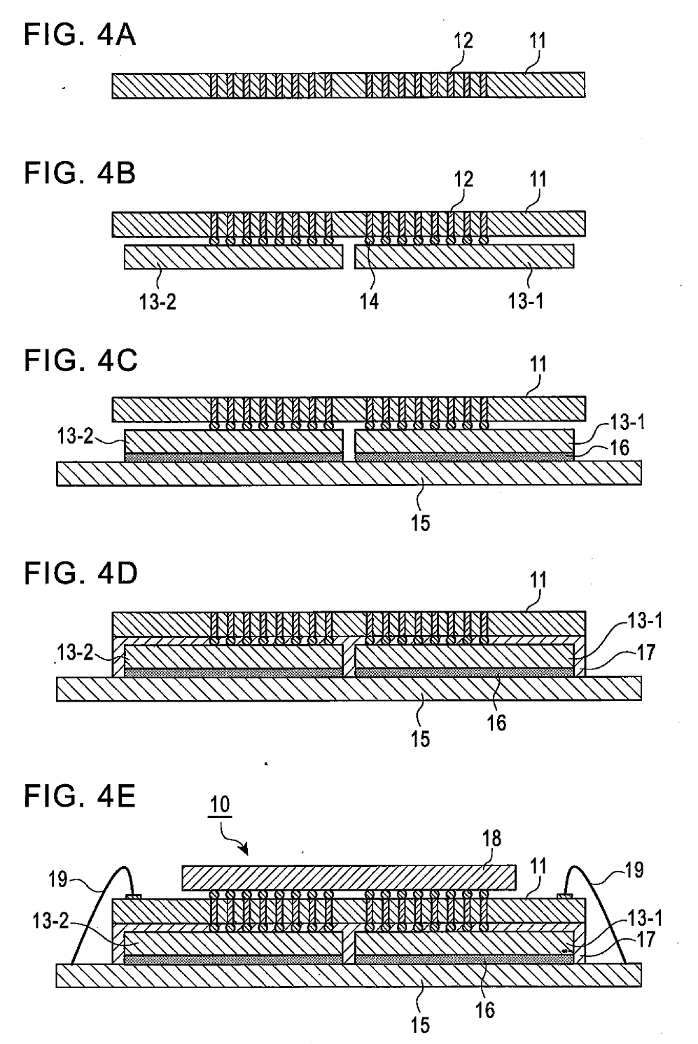

FIG. 3 is a flowchart showing the flow of manufacture of the semiconductor device 10. FIG. 4A to FIG. 4E show a series of manufacturing steps for the semiconductor device 10. In the following, each manufacturing step for the semiconductor device 10 is explained with reference to FIG. 3 and FIG. 4A to FIG. 4E.

First, the mounting substrate 11 and the supporting substrate 15 are prepared (Step S101). The mounting substrate 11 is, for example, one of silicon substrates obtained by separating a plurality of substrates formed on a single silicon wafer into individual substrates. The supporting substrate 15 is for example a multi-layer printed circuit board on which a plurality of wiring layers and power supply layers is laminated. Elements such as for example condensers or the like may be mounted on the surface of the supporting substrate 15 when necessary.

Next, penetrating electrodes 12 are formed in the mounting substrate 11 (Step S102, FIG. 4A). For example, through holes may be mechanically formed in the mounting substrate 11 from the top surface to the bottom surface, and the penetrating electrodes 12 are formed by filling the through holes with an electrically conducting material such as copper or the like. The penetrating electrodes 12 may be arranged in the mounting substrate 11 in, for example, a rectangular or square lattice form. If necessary an electrically insulating material or element may be provided over and/or around the penetrating electrodes 12.

Next, the semiconductor chips 13-1 and 13-2 are mounted on the bottom surface of the mounting substrate 11 (Step S103, FIG. 4B). For example, bumps 14 are formed such that the bumps 14 are electrically connected to a plurality of electrode pads (not shown on the drawings) formed on the surface of the semiconductor chip 13-1. Then the bumps 14 are joined to the penetrating electrodes 12 formed in the mounting substrate 11 such that the bumps 14 are physically and electrically connected to the penetrating electrodes 12. This joining is achieved by, for example, normal thermo-compression bonding (heat-pressing). In this way the semiconductor chip 13-1 is fixed to the mounting substrate 11 by the bumps 14. The semiconductor chip 13-2 is mounted on the bottom surface of the mounting substrate 11 by the same method as in the case of the semiconductor chip 13-1. The semiconductor chip 13-2 is mounted on the mounting substrate 11, either simultaneously with the semiconductor chip 13-1 or separately. The semiconductor chips 13-1 and 13-2 are arranged side by side on the mounting substrate 11. There is no limitation on the number of semiconductor chips mounted on the bottom surface of the mounting substrate 11. For example the number may be one, or it may be three or more.

Next, the mounting substrate 11 is mounted on the supporting substrate 15 (Step S104, FIG. 4C). Specifically, the semiconductor chips 13-1 and 13-2 mounted on the mounting substrate 11 are fixed to the supporting substrate 15 by the adhesive 16. The bottom surface of the semiconductor chip 13-1 (i.e., the opposite surface to the surface fixed to the mounting substrate 11) is fixed to the supporting substrate 15. There is no limitation on the adhesive 16, and it may be, for example, an epoxy adhesive. Likewise the bottom surface of the semiconductor chip 13-2 is fixed to the supporting substrate 15.

In the mounting step of Step S104, the semiconductor chips 13-1 and 13-2 are not sealed with the resin 17. Thus, warping of the mounting substrate 11 due to thermal shrinkage of the resin 17 does not occur, and it is possible to properly fix the mounting substrate 11 to the supporting substrate 15.

Next, the semiconductor chips 13-1 and 13-2 mounted on the bottom surface of the mounting substrate 11 are sealed with the resin 17 (Step S105, FIG. 4D). The resin 17 is for example an electrically insulating resin such as epoxy resin or the like. Preferably a filler whose diameter is several μm or less is included in the resin 17. As shown in FIG. 4D, liquefied fluid resin 17 is filled by injecting between the bottom surface of the mounting substrate 11 and the top surface of the supporting substrate 15 from the lateral side. After filling, the resin 17 is hardened and fixed by thermal processing or the like. In this way, the semiconductor chips 13-1 and 13-2 are embedded in the resin 17.

The semiconductor chips 13-1 and 13-2 are fixed to the supporting substrate 15 by the adhesive 16. Therefore, even if there is thermal shrinkage of the resin 17, the mounting position of the semiconductor chips 13-1 and 13-2 on the supporting substrate 15 is not changed, and warping does not occur in the mounting substrate 11 to which the semiconductor chips 13-1 and 13-2 are fixed by the bumps 14.

Next, the third semiconductor chip 18 is mounted on the top surface of the mounting substrate 11 (Step S106, FIG. 4E). For example, upper bumps 14 are provided electrically connected to a plurality of electrode pads (not shown on the drawings) formed on the bottom surface of the semiconductor chip 18, and then the penetrating electrodes 12 formed in the mounting substrate 11 are joined to the upper bumps 14 by normal thermo-compression bonding or the like so that the penetrating electrodes 12 and the bumps 14 are physically and electrically connected to each other. In this way, the semiconductor chip 18 is fixed to the mounting substrate 11 by the upper bumps 14. Warping does not occur in the mounting substrate 11 due to thermal shrinkage of the resin 17. Thus, the semiconductor chip 18 can be properly mounted on the mounting substrate 11.

Next, electrodes (not shown on the drawings) formed on the surface of the mounting substrate 11 and electrodes (not shown on the drawings) formed on the surface of the supporting substrate 15 are electrically connected to each other using wire 19 (Step S107). The material of the wire 19 is aluminum, for example. The connections with the wire 19 may be carried out using a normal wire bonding method. As a result of the above-described manufacturing steps, the semiconductor device 10 is completed.

In the semiconductor device manufacturing method according to the present invention as described above, the semiconductor chips 13-1, 13-2 and so on are mounted on the bottom surface of the mounting substrate 11, and before sealing the semiconductor chips 13-1, 13-2 and so on with the resin 17, the semiconductor chips 13-1, 13-2 and so on are fixed to the supporting substrate 15 by the adhesive 16. In these fixing steps, the semiconductor chips 13-1, 13-2 and so on are not sealed with the resin 17. Thus, warping of the mounting substrate 11 due to thermal shrinkage of the resin 17 does not occur. Accordingly, the mounting substrate 11 can be fixed to the supporting substrate 15 in a desired manner.

After the semiconductor chips 13-1, 13-2 and so on are fixed to the supporting substrate 15 by the adhesive 16, the semiconductor chips 13-1, 13-2 and so on are sealed with resin 17. Thus, even if thermal shrinkage of the resin 17 occurs, the mounting positions of the semiconductor chips 13-1, 13-2 and so on will not change, and warping of the mounting substrate 11 to which the semiconductor chips 13-1, 13-2 and so on are fixed by the bumps 14 does not occur. Because warping of the mounting substrate 11 due to thermal shrinkage of the resin 17 does not occur, it is possible to mount the semiconductor chip 18 on the mounting substrate 11 in a desired manner. It should be noted that warping of the mounting substrate 11 does not occur as long as the semiconductor chips 13-1 and 13-2 are fixed to the supporting substrate 15. Thus, use of the adhesive 16 in fixing the semiconductor chips 13-1 and 13-2 to the supporting substrate 15 is not mandatory. For example, the semiconductor chips 13-1 and 13-2 may be mechanically fixed by a fixing frame, a gripper or the like.

In the semiconductor device manufacturing method according to the present embodiment, the semiconductor chip 18 is mounted on the mounting substrate 11 after fixing the semiconductor chips 13-1, 13-2 and so on to the supporting substrate 15 and sealing them with resin 17. By sealing with the resin 17 and fixing with the adhesive 16, the fixing between the semiconductor chips 13-1, 13-2 and so on and the mounting substrate 11 and the supporting substrate 15 is strengthened. Accordingly, it is possible to prevent the semiconductor chips 13-1, 13-2 and soon from shifting or falling from the mounting substrate 11 due to shock when the semiconductor chip 18 is being mounted on the mounting substrate 11.

In the case where in Step S103 a plurality of semiconductor chips are arranged and mounted on the mounting substrate 11 in the horizontal direction, as shown in FIG. 4B, the following advantages are obtained compared with the case where a plurality of semiconductor chips are stacked in the vertical direction and mounted on the mounting substrate 11. Namely, in Step S104 (FIG. 4C), when fixing the semiconductor chips to the supporting substrate 15 using the adhesive 16, the adhesion area is large compared with vertical stacked mounting, and therefore it is possible to more strongly fix the semiconductor chips to the supporting substrate 15. As a result, in Step S105 (FIG. 4D), when the semiconductor chips that have been mounted on the bottom surface of the mounting substrate 11 are sealed with the resin 17, the semiconductor chips are not affected by thermal shrinkage of the resin 17. Therefore, it is possible to prevent warping of the mounting substrate 11 on which the semiconductor chips are fixed.

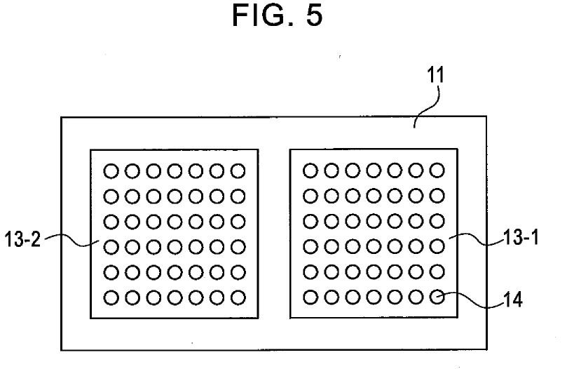

FIG. 5 shows the mounting substrate 11 viewed from the bottom surface when two semiconductor chips 13-1, 13-2 have been mounted side by side in the horizontal direction on the mounting substrate 11. By mounting the semiconductor chips in this way, the area of adhesive becomes large, the semiconductor chips can be fixed more strongly to the supporting substrate 15, and it is possible to prevent warping of the mounting substrate 11. It should be noted that there is no particular limitation on the size of each semiconductor chip.

According to the semiconductor device manufacturing method of the present embodiment as described above, warping of the mounting substrate 11 does not occur, even when a plurality of semiconductor chips is mounted on the mounting substrate 11. Therefore, it is possible to stably fix the mounting substrate 11 to the supporting substrate 15, and the semiconductor chips can be stably mounted on the mounting substrate 11. Consequently, it is possible to manufacture semiconductor devices 10 that operate properly.

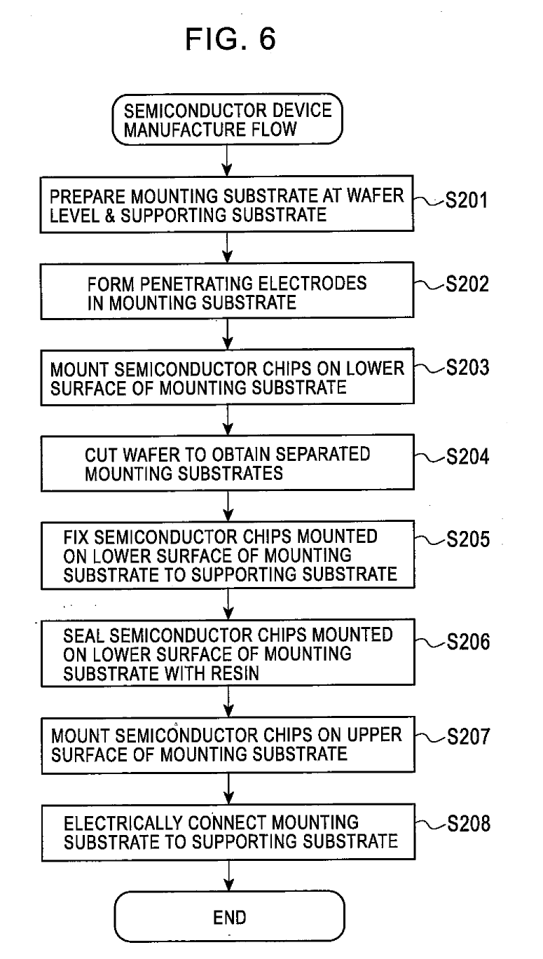

In the above-described embodiment, the semiconductor chips 13-1, 13-2 and so on are mounted on the mounting substrate 11 after separation (individualization of the mounting substrates from a wafer). The present invention is not limited in this regard. Specifically, the semiconductor chips 13-1, 13-2 and so on may be mounted on the mounting substrate 11 at the wafer level stage prior to separation. FIG. 6 is a flowchart showing the flow of manufacture of the semiconductor device in this case. This modification (i.e., the second embodiment) is described below with reference to FIG. 6. First, a silicon wafer on which a plurality of mounting substrates 11 is formed and the supporting substrate 15 are prepared (Step S201). Next, penetrating electrodes 12 are provided in each of the mounting substrates 11 formed on the silicon wafer (Step S202). The process of forming the penetrating electrodes 12 is the same as in the first embodiment (FIG. 2 to FIG. 5). Next, the semiconductor chips 13-1 and 13-2 are mounted on each of the mounting substrates 11 formed on the silicon wafer (Step S203). The mounting method is the same as that described in the first embodiment. Next, the silicon wafer is diced to obtain the separated mounting substrates 11 (Step S204). The processes in Step S205 to Step S208 in the second embodiment are the same processes as Step S104 to Step S107 in the first embodiment.

When the semiconductor device 10 is manufactured by the procedure of FIG. 6, warping of the mounting substrate 11 due to thermal shrinkage of the resin 17 does not occur. Thus, it is possible to stably fix the mounting substrate 11 to the supporting substrate 15, and it is possible to stably mount the semiconductor chip 18 on the mounting substrate 11.

This application is based on Japanese Patent Application No. 2008-225828 filed on Sep. 3, 2008, and the entire disclosure thereof is incorporated herein by reference.

What is claimed is:

1. A method of manufacturing a semiconductor device that has a plurality of semiconductor chips, comprising:
a substrate preparation step of preparing amounting substrate and a supporting substrate;
a bottom surface mounting step of firmly mounting at least one semiconductor chip on a bottom surface of the mounting substrate;
a chip fixing step of fixing the at least one semiconductor chip mounted on the bottom surface of the mounting substrate, to one surface of the supporting substrate;
a resin sealing step of sealing the at least one semiconductor chip mounted on the bottom surface of the mounting substrate using resin; and
a top surface mounting step of mounting at least one second semiconductor chip on a top surface of the mounting substrate.

2. The semiconductor device manufacturing method according to claim 1, further comprising, prior to the bottom surface mounting step, an electrode forming step of providing at least one penetrating electrode in the mounting substrate such that the at least one penetrating electrode extends from the top surface to the bottom surface of the mounting substrate.

3. The semiconductor device manufacturing method according to claim 2, wherein first electrode pads are provided on the at least one semiconductor chip, and the bottom surface mounting step is carried out such that the first electrode pads are electrically connected to the at least one penetrating electrode, and
wherein second electrode pads are provided on the at least one second semiconductor chip, and the top surface mounting step is carried out such that the second electrode pads are electrically connected to the at least one penetrating electrode.

4. The semiconductor device manufacturing method according to claim 1, wherein the at least one semiconductor chip includes a plurality of semiconductor chips that are arrange side by side on the bottom surface of the mounting substrate.

5. The semiconductor device manufacturing method according to claim 1 further comprising an insulation step of providing an insulation material over the at least one penetrating electrode.

6. The semiconductor device manufacturing method according to claim 1, wherein the bottom surface mounting step is carried out by heat pressing.

7. The semiconductor device manufacturing method according to claim 1, wherein the chip fixing step is carried out using adhesive.

8. The semiconductor device manufacturing method according to claim 1, wherein the chip fixing step is carried out using a mechanical gripper.

9. The semiconductor device manufacturing method according to claim 1, wherein the resin used in the resin sealing step includes a filler such as silica with several micrometer diameter.

10. The semiconductor device manufacturing method according to claim 1 further comprising a hardening step of heating the resin to harden the resin, prior to the top surface mounting step.

11. A method of manufacturing a semiconductor device that has a plurality of semiconductor chips, comprising:
a wafer preparation step of preparing a wafer that has a plurality of mounting substrates;
a substrate preparation step of preparing a plurality of supporting substrates;
a bottom surface mounting step of firmly mounting at least one semiconductor chip on a bottom surface of each said mounting substrate on the wafer;
a dicing step of dicing the wafer to obtain a plurality of individual mounting substrates;
a chip fixing step of fixing the at least one semiconductor chip mounted on the bottom surface of each said individual mounting substrate, to one surface of each said supporting substrate;
a resin sealing step of sealing the at least one semiconductor chip mounted on the bottom surface of each said individual mounting substrate using resin; and
a top surface mounting step of mounting at least one second semiconductor chip on a top surface of each said individual mounting substrate.

12. The semiconductor device manufacturing method according to claim 11, further comprising, prior to the bottom surface mounting step, an electrode forming step of providing at least one penetrating electrode in each said mounting substrate such that the at least one penetrating electrode extends from the top surface to the bottom surface of each said mounting substrate.

13. The semiconductor device manufacturing method according to claim 12, wherein first electrode pads are provided on the at least one semiconductor chip, and the bottom surface mounting step is carried out such that the first electrode pads are electrically connected to the at least one penetrating electrode, and
wherein second electrode pads are provided on the at least one second semiconductor chip, and the top surface mounting step is carried out such that the second electrode pads are electrically connected to the at least one penetrating electrode.

14. The semiconductor device manufacturing method according to claim 11, wherein the at least one semiconductor chip includes a plurality of semiconductor chips that are arrange side by side on the bottom surface of each said mounting substrate.

15. The semiconductor device manufacturing method according to claim 11 further comprising an insulation step of providing an insulation material over the at least one penetrating electrode.

16. The semiconductor device manufacturing method according to claim 11, wherein the bottom surface mounting step is carried out by heat pressing.

17. The semiconductor device manufacturing method according to claim 11, wherein the chip fixing step is carried out using adhesive.

18. The semiconductor device manufacturing method according to claim 11, wherein the chip fixing step is carried out using a mechanical gripper.

19. The semiconductor device manufacturing method according to claim 11, wherein the resin used in the resin sealing step includes a filler such as silica with several micrometer diameter.

20. The semiconductor device manufacturing method according to claim 11 further comprising a hardening step of heating the resin to harden the resin, prior to the top surface mounting step.
